(19) United States
(12) Patent Application Publication
(10) Pub. No.: US 2024/0184061 A1
(43) Pub. Date: Jun. 6, 2024

(54) OPTICAL COUPLER

(71) Applicant: Murata Manufacturing Co., Ltd., Nagaokakyo-shi (JP)

(72) Inventors: Kazuho SHIMADA, Nagaokakyo-shi (JP); Yasuhiro SHIMIZU, Nagaokakyo-shi (JP); Masaki NAGATA, Nagaokakyo-shi (JP); Naoya MORI, Nagaokakyo-shi (JP)

(21) Appl. No.: 18/440,089

(22) Filed: Feb. 13, 2024

Related U.S. Application Data
(63) Continuation of application No. PCT/JP2022/016587, filed on Mar. 31, 2022.

(30) Foreign Application Priority Data
Aug. 26, 2021 (JP) 2021-137742

(51) Int. Cl. G02B 6/42

(52) U.S. Cl. CPC G02B 6/4214; G02B 6/423

(57) ABSTRACT

An optical coupler that includes: a first optical member including one or more condensing lenses that concentrate light traveling in a positive direction of an X-axis; a fixing unit that fixes one or more optical fibers; and a support member having a first portion extending in the X-axis direction, a second portion extending in the X-axis direction, and a third portion extending in a Y-axis direction orthogonal to the X-axis direction. The third portion, the first optical member, and the fixing unit are arranged at intervals in this order in a positive direction of an X-axis. The third portion, the first optical member, and the fixing unit are positioned between the first portion and the second portion as viewed in the Z-axis direction. The third portion, the first optical member, and the fixing unit are fixed to the first portion and the second portion.

### CROSS REFERENCE TO RELATED APPLICATIONS

The present application is a continuation of International application No. PCT/JP2022/016587, filed Mar. 31, 2022, which claims priority to Japanese Patent Application No. 2021-137742, filed Aug. 26, 2021, the entire contents of each of which are incorporated herein by reference.

### TECHNICAL FIELD

The present invention relates to an optical coupler that changes a traveling direction of light.

### BACKGROUND ART

In the related art, a light-emitting module described in Patent Document 1 is known as an invention related to an optical component. A laser beam travels on an optical path in the light-emitting module. Specifically, the light-emitting module includes a light-emitting element, a microlens, a reflective prism, and an optical fiber guide groove structure. The light-emitting element outputs the laser beam. The microlens collimates the laser beam. The reflective prism changes a traveling direction of the laser beam. The optical fiber guide groove structure fixes an optical fiber. The optical fiber receives the laser beam traveling based on the optical path.
Patent Document 1: Japanese Patent Application Laid-Open No. 2006-126754

### SUMMARY OF THE INVENTION

Incidentally, in the field of optical components described in Patent Document 1, an optical coupler in which a deviation in an optical axis is hardly caused is desired.

An object of the present invention is to provide an optical coupler capable of reducing a possibility that a deviation is caused in an optical axis.

The inventor of the present application has studied causes of the deviation in the optical axis of the optical coupler. As a result, the inventor of the present application has noticed that there is a possibility that heat generated from a component present around the optical coupler affects the optical axis of the optical coupler. The inventor of the present application has noticed that, for example, in a case where an electronic component such as an IC chip is present around the optical coupler, there is a possibility that a temperature of the optical coupler rises due to heat generated from an electronic component. In this case, the inventor of the present application has noticed that there is a possibility that a deviation is caused in the optical axis of the optical coupler due to thermal expansion of the optical coupler.

Therefore, the inventor of the present application has studied a method for hardly causing the deviation in the optical axis of the optical coupler due to the thermal expansion of the optical coupler. As a result, the inventor of the present application conceived the following invention.

An optical coupler according to an embodiment of the present invention includes: a first optical member including one or more condensing lenses that concentrate light traveling in an X-axis direction; a fixing unit that fixes one or more optical fibers; and a support member having a first portion extending in the X-axis direction, a second portion extending in the X-axis direction, and a third portion extending in a Y-axis direction orthogonal to the X-axis direction. The first portion is present at a position different from the second portion in the Y-axis direction. The first optical member, the fixing unit, and the support member are disposed not to overlap each other as viewed in a Z-axis direction orthogonal to the X-axis direction and the Y-axis direction. The third portion, the first optical member, and the fixing unit are arranged at intervals in this order in a positive direction of the X-axis. The third portion, the first optical member, and the fixing unit are positioned between the first portion and the second portion as viewed in the Z-axis direction. Each of the third portion, the first optical member, and the fixing unit are fixed to the first portion and the second portion.

In the optical coupler according to the present invention, the possibility that the deviation is caused in the optical axis of the optical coupler is reduced.

### BRIEF EXPLANATION OF THE DRAWINGS

FIG. 1 is an external perspective view of an optical coupler 10 according to a first embodiment.

FIG. 2 is a top view of the optical coupler 10.

FIG. 3 is an external perspective view of an optical coupler 10a according to a first modification of the optical coupler 10.

FIG. 4 is a top view of an optical coupler 10b according to a second modification of the optical coupler 10.

FIG. 5 is a top view of an optical coupler 10c according to a modification of the optical coupler 10b.

FIG. 6 is an external perspective view of an optical coupler 10d according to third modification of the optical coupler 10.

FIG. 7 is a top view of an optical coupler 20 according to a second embodiment.

FIG. 8 is a top view of an optical coupler 20a according to a first modification of the optical coupler 20.

FIG. 9 is a top view of an optical coupler 20b according to a second modification of the optical coupler 20.

FIG. 10 is a top view of an optical coupler 30 according to a third embodiment.

FIG. 11 is an external perspective view of an optical coupler 40 according to a fourth embodiment.

FIG. 12 is an external perspective view of the optical coupler 40, and is a diagram in which ball lenses BL1 to BL5 are not illustrated.

FIG. 13 is a sectional view of an optical coupler 50 according to a fifth embodiment.

### DETAILED DESCRIPTION OF THE INVENTION

### First Embodiment

### [Structure of Optical Coupler 10]

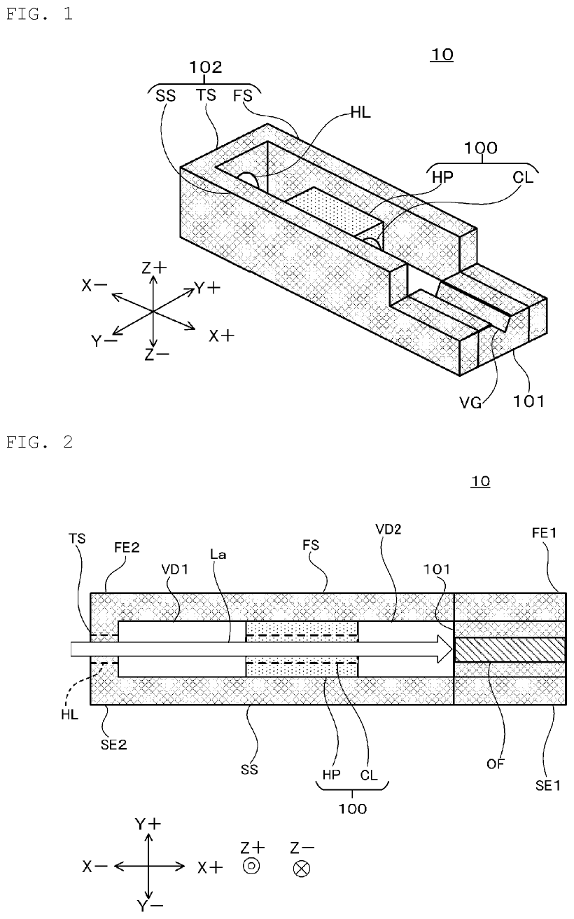

Hereinafter, an optical coupler 10 according to a first embodiment will be described with reference to the drawings. FIG. 1 is an external perspective view of the optical coupler 10 according to the first embodiment. In order to easily understand the description, the description of an optical fiber OF is omitted in FIG. 1. FIG. 2 is a top view of the optical coupler 10. In FIG. 2, a traveling direction of a laser La is indicated by an arrow.

In the present specification, directions are defined as illustrated in FIGS. 1 and 2. Specifically, a direction in which a first optical member 100 and a fixing unit 101 are arranged is defined as an X-axis direction. At this time, a direction in which the first optical member 100 and the fixing unit 101 are arranged in this order is defined as a positive direction of an X-axis. Similarly, a direction in which a first portion FS and a second portion SS are arranged is defined as a Y-axis direction. At this time, a direction in which the second portion SS and the first portion FS are arranged in this order is defined as a positive direction of a Y-axis. The X-axis direction and the Y-axis direction are orthogonal to each other. Similarly, a direction orthogonal to the X-axis direction and the Y-axis direction is defined as a Z-axis direction. The X-axis direction, the Y-axis direction, and the Z-axis direction in the present specification are directions defined for the sake of convenience in description. Accordingly, the X-axis direction, the Y-axis direction, and the Z-axis direction in the present specification does not have to coincide with the X-axis direction, the Y-axis direction, and the Z-axis direction in actual use of the optical coupler 10.

Hereinafter, M and N are components or members of the optical coupler 10. In the present specification, each part of M is defined as follows unless otherwise specified. An end portion of M in the positive direction of the X-axis means an end of M in the positive direction of the X-axis and the vicinity thereof. An end portion of M in a negative direction of the X-axis means an end of M in the negative direction of the X-axis and the vicinity thereof. An end portion of M in the positive direction of the Y-axis means an end of M in the positive direction of the Y-axis and the vicinity thereof. An end portion of M in a negative direction of the Y-axis means an end of M in the negative direction of the Y-axis and the vicinity thereof. An end portion of M in a positive direction of the Z axis means an end of M in the positive direction of the Z axis and the vicinity thereof. An end portion of M in a negative direction of the Z axis means an end of M in the negative direction of the Z axis and the vicinity thereof.

The optical coupler 10 is a device for concentrating light emitted from a light-emitting element or the like and inputting the collected light to an optical fiber. For example, as illustrated in FIG. 2, the laser La is incident on the optical coupler 10. The optical coupler 10 concentrates the emitted laser La. The concentrated laser La is incident on the optical fiber OF. The optical coupler 10 includes the first optical member 100, the fixing unit 101, and a support member 102. As illustrated in FIGS. 1 and 2, the first optical member 100, the fixing unit 101, and the support member 102 are disposed not to overlap each other as viewed in the Z-axis direction.

The first optical member 100 is a member that concentrates light. Specifically, the first optical member 100 includes one or more condensing lenses CL and holding units HP. As illustrated in FIG. 2, the condensing lens CL concentrates light traveling in the positive direction of the X-axis. In other words, in the present embodiment, the condensing lens CL concentrates the laser La. In the present embodiment, the condensing lens CL has a cylindrical shape extending in the X-axis direction. The holding unit HP holds the condensing lens CL. Specifically, the holding unit HP surrounds a periphery of the condensing lens CL. More specifically, the holding unit HP surrounds a cylindrical curved surface of the condensing lens CL. Thus, the condensing lens CL is fixed by the holding unit HP. The main component of the condensing lens CL and the main component of the holding unit HP are the same. The condensing lens CL and the holding unit HP are molded by using, for example, a glass material containing silicon (Si) or silicon oxide (SiO₂) as a main component. Here, the fact that silicon or silicon oxide is the main component means that, for example, silicon or silicon oxide has a largest mass mole percentage among one or more components contained in glass. A component other than the main component of the condensing lens CL and a component other than the main component of the holding unit HP may be different.

The fixing unit 101 is a member containing glass as a main component. As illustrated in FIG. 2, the fixing unit 101 fixes one or more optical fibers OF. Specifically, the fixing unit 101 includes one or more grooves VG having a V shape as viewed in the X-axis direction. Then, the optical fiber OF is fixed to the groove VG. In the present embodiment, one optical fiber OF is fixed to the groove VG (see FIG. 2). At this time, the optical fibers OF arranged in the X-axis direction are optically coupled to the condensing lens CL. Thus, the optical fiber OF receives the laser La having passed through the condensing lens CL.

The support member 102 is a member containing glass as a main component. Specifically, the support member 102 contains a glass material having a filler. The first optical member 100 and the fixing unit 101 are fixed to the support member 102. Details will be described below.

As illustrated in FIG. 1, the support member 102 includes the first portion FS, the second portion SS, and a third portion TS. As illustrated in FIGS. 1 and 2, the first portion FS, the second portion SS, the first optical member 100, and the fixing unit 101 are disposed not to overlap each other as viewed in the Z-axis direction. In other words, the first portion FS is present at a position different from the second portion SS in the Y-axis direction. More specifically, the first portion FS and the second portion SS are arranged at intervals in this order in the negative direction of the Y-axis. In addition, the first optical member 100 and the fixing unit 101 are positioned between the first portion FS and the second portion SS as viewed in the Z-axis direction.

The first portion FS extends in the X-axis direction. In the present embodiment, the first portion FS has a plate shape extending in the X-axis direction. The first optical member 100 is fixed to the first portion FS. Specifically, the end of the first optical member 100 in the positive direction of the Y-axis is fixed to the first portion FS (see FIGS. 1 and 2). Similarly, the fixing unit 101 is fixed to the first portion FS. More specifically, the end portion of the first portion FS in the positive direction of the X-axis is defined as a first-portion first end portion FE1 (see FIG. 2). At this time, the fixing unit 101 is fixed to the first-portion first end portion FE1.

The second portion SS extends in the X-axis direction. In the present embodiment, the second portion SS has a plate shape extending in the X-axis direction. The first optical member 100 is fixed to the second portion SS. Specifically, the end of the first optical member 100 in the negative direction of the Y-axis is fixed to the second portion SS (see FIGS. 1 and 2). Similarly, the fixing unit 101 is fixed to the second portion SS. More specifically, the end of the second portion SS in the positive direction of the X-axis is defined as a second-portion first end portion SE1 (see FIG. 2). At this time, the fixing unit 101 is fixed to the second-portion first end portion SE1.

The third portion TS is a plate-shaped member connecting the first portion FS and the second portion SS. Specifically, the third portion TS extends in the Y-axis direction. In addition, the third portion TS is positioned between the first portion FS and the second portion SS. The third portion TS is fixed to the first portion FS and the second portion SS. More specifically, the end portion of the first portion FS in the negative direction of the X-axis is defined as a first-portion second end portion FE2 (see FIG. 2). In addition, the end portion of the second portion SS in the negative direction of the X-axis is defined as a second-portion second end portion SE2. At this time, in the present embodiment, the third portion TS is fixed to the first-portion second end portion FE2 and the second-portion second end portion SE2.

The third portion TS does not overlap the first optical member 100 and the fixing unit 101 as viewed in the Z-axis direction. Specifically, the third portion TS, the first optical member 100, and the fixing unit 101 are arranged at intervals in this order in the positive direction of the X-axis. In this case, a gap VD1 is present between the third portion TS and the first optical member 100. The gap VD1 penetrates the optical coupler 10 in the Z-axis direction (see FIG. 2). Similarly, a gap VD2 is present between the first optical member 100 and the fixing unit 101. The gap VD2 penetrates the optical coupler 10 in the Z-axis direction.

In the present embodiment, a through-hole HL is provided in the third portion TS (see FIGS. 1 and 2). The through-hole HL penetrates the third portion TS in the X-axis direction. The through-hole HL has, for example, a cylindrical shape. In the present embodiment, the laser La reaches the first optical member 100 through through-hole HL.

### (Effect of Optical Coupler 10)

According to the optical coupler 10, it is possible to reduce a possibility that an optical axis of the optical coupler 10 is shifted. In the optical coupler 10, for example, when a temperature of the support member 102 rises, the first portion FS tends to be deformed due to thermal expansion. At this time, forces (hereinafter, referred to as force A) in the X-axis direction and the Y-axis direction are applied to the first portion FS. However, in the optical coupler 10, the third portion TS, the first optical member 100, and the fixing unit 101 are arranged at intervals in this order in the positive direction of the X-axis, and the first optical member 100 is fixed to the first portion FS and the second portion SS. That is, in the optical coupler 10, the first optical member 100 is fixed to the first portion FS and the second portion SS between the third portion TS and the fixing unit 101. Thus, for example, when the first portion FS is pulled in the positive direction of the Y-axis due to thermal expansion, the first portion FS is pulled in the negative direction of the Y-axis by the first optical member 100 fixed to the second portion SS. In other words, a force (hereinafter, referred to as force B) is applied to the first portion FS in a direction opposite to the force A. Thus, the first portion FS is hardly deformed at and in the vicinity of a center of the first portion FS in the X-axis direction. In other words, the optical coupler 10 is hardly deformed due to thermal expansion. As a result, the possibility that the optical axis of the optical coupler 10 is shifted is reduced. Thus, for example, in a case where an electrical component or the like is present around the optical coupler 10, the possibility that the optical axis of the optical coupler 10 is shifted due to heat generated from the electrical component or the like is reduced.

For the same reason, for example, when the second portion SS is pulled in the negative direction of the Y-axis due to thermal expansion, the second portion SS is pulled in the positive direction of the Y-axis by the first optical member 100. Thus, the second portion SS is hardly deformed. In other words, the optical coupler 10 is hardly deformed due to thermal expansion. As a result, the possibility that the optical axis of the optical coupler 10 is shifted is reduced.

### (First Modification of Optical Coupler 10)

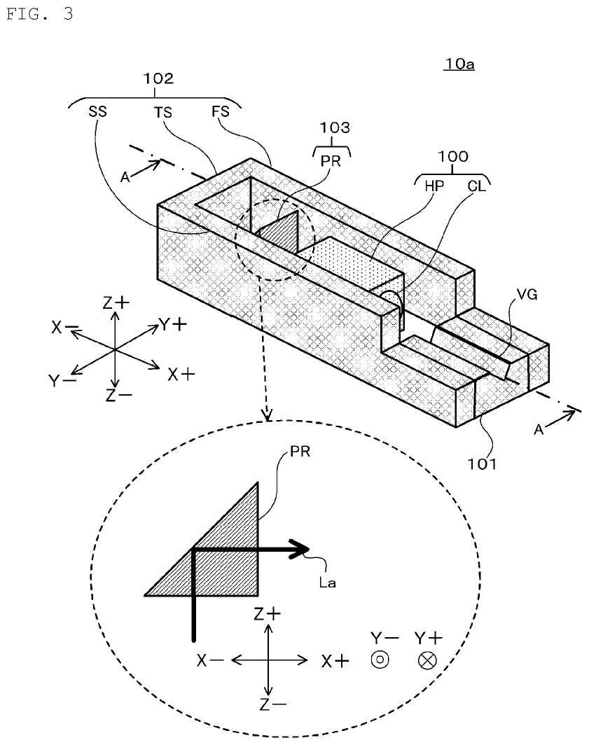

Hereinafter, an optical coupler 10a according to a first modification of the optical coupler 10 will be described with reference to the drawings. FIG. 3 is an external perspective view of the optical coupler 10a according to the first modification of the optical coupler 10. Note that, in FIG. 3, the optical fiber OF is not illustrated. The optical coupler 10a is different from the optical coupler 10 in that the through-hole HL is not provided in the third portion TS. In the present modification, the laser La reaches the optical fiber OF without passing through the through-hole HL. Details will be described below. Note that, the same configurations as those of the optical coupler 10 are denoted by the same reference symbols, and description thereof is omitted.

As illustrated in FIG. 3, the optical coupler 10a includes a second optical member 103. The second optical member 103 includes a prism PR. As illustrated in FIG. 3, the prism PR changes the traveling direction of the light from the Z-axis direction to the X-axis direction orthogonal to the Z-axis direction. Accordingly, in the present modification, the laser La reaches the optical fiber OF through the prism PR.

The second optical member 103 is fixed to the support member 102. Specifically, the second optical member 103 is positioned between the third portion TS and the first optical member 100 in the X-axis direction. The second optical member 103 is fixed to the first portion FS and the second portion SS. The second optical member 103 does not overlap the fixing unit 101 and the support member 102 as viewed in the Z-axis direction.

### (Effect of Optical Coupler 10a)

According to the optical coupler 10a, it is possible to reduce a possibility that an optical axis of the optical coupler 10a is shifted. More specifically, the second optical member 103 is positioned between the third portion TS and the first optical member 100 in the X-axis direction. The second optical member 103 does not overlap the fixing unit 101 and the support member 102 as viewed in the Z-axis direction. In this case, the second optical member 103 is fixed to the first portion FS and the second portion SS between the third portion TS and the first optical member 100. Thus, the first portion FS and the second portion SS are hardly deformed by the second optical member 103 in addition to the first optical member 100. Accordingly, the possibility that the optical axis of the optical coupler 10a is shifted is reduced.

### (Second Modification of Optical Coupler 10)

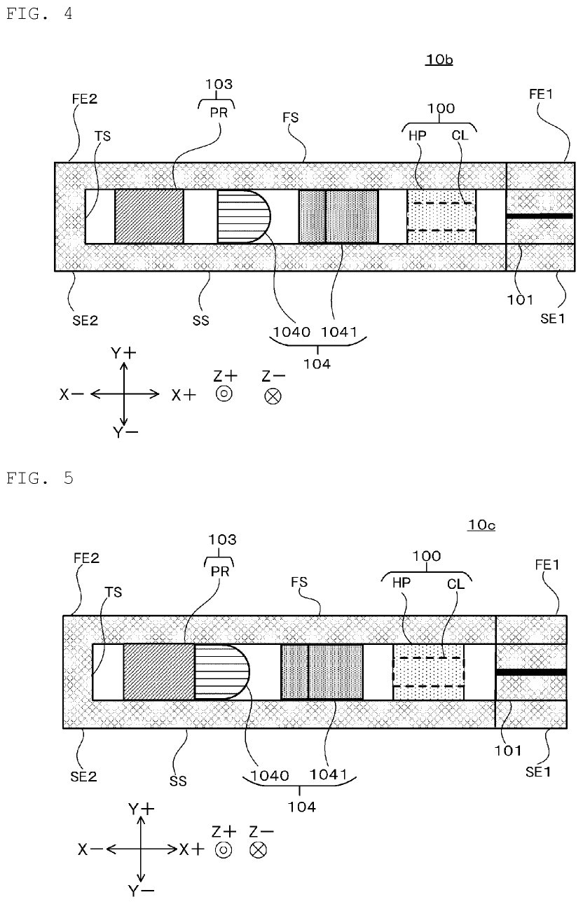

Hereinafter, an optical coupler 10b according to a second modification of the optical coupler 10 will be described with reference to the drawings. FIG. 4 is a top view of the optical coupler 10b according to Modification 2 of the optical coupler 10. Note that, in FIG. 4, the optical fiber OF is not illustrated. The optical coupler 10b is different from the optical coupler 10 in including a third optical member 104. Details will be described below.

As illustrated in FIG. 4, the optical coupler 10b includes the third optical member 104. The third optical member 104 includes one or more collimator lenses. The collimator lens is a lens that adjusts a beam shape of the laser La. Specifically, the collimator lens corrects the traveling direction of the laser La such that the traveling direction of the laser La incident on the optical coupler 10b becomes parallel to the X-axis direction. In the present modification, the third optical member 104 includes a first collimator lens 1040 and a second collimator lens 1041. The first collimator lens 1040 corrects a shape of light spreading in a fast axis direction. The first collimator lens 1040 is, for example, a fast axis collimator (FAC) or the like. The second collimator lens 1041 corrects a shape of light spreading in a slow axis direction. The second collimator lens 1041 is, for example, a slow axis collimator (SAC) or the like.

The third optical member 104 is disposed not to overlap the second optical member 103, the first optical member 100, the fixing unit 101, and the support member 102 as viewed in the Z-axis direction. The third optical member 104 is positioned between the first optical member 100 and the second optical member 103 in the X-axis direction. In the present modification, the first collimator lens 1040 and the second collimator lens 1041 are positioned between the first optical member 100 and the second optical member 103. Specifically, the second optical member 103, the first collimator lens 1040, the second collimator lens 1041, and the first optical member 100 are arranged in this order at intervals in the positive direction of the X-axis.

The third optical member 104 is fixed to the first portion FS and the second portion SS. In the present modification, the first collimator lens 1040 and the second collimator lens 1041 are fixed to the first portion FS and the second portion SS, respectively, as viewed in the Z-axis direction.

### (Effect of Optical Coupler 10b)

According to the optical coupler 10b, it is possible to reduce a possibility that an optical axis of the optical coupler 10b is shifted. More specifically, the third optical member 104 does not overlap the second optical member 103, the first optical member 100, the fixing unit 101, and the support member 102 as viewed in the Z-axis direction. The third optical member 104 is fixed to the first portion FS and the second portion SS. In this case, the third optical member 104 is fixed to the first portion FS and the second portion SS between the first optical member 100 and the second optical member 103. Accordingly, in addition to the first optical member 100 and the second optical member 103, the first portion FS and the second portion SS are hardly deformed by the third optical member 104. Thus, the possibility that the optical axis of the optical coupler 10b is shifted is reduced.

### (Modification of Optical Coupler 10b)

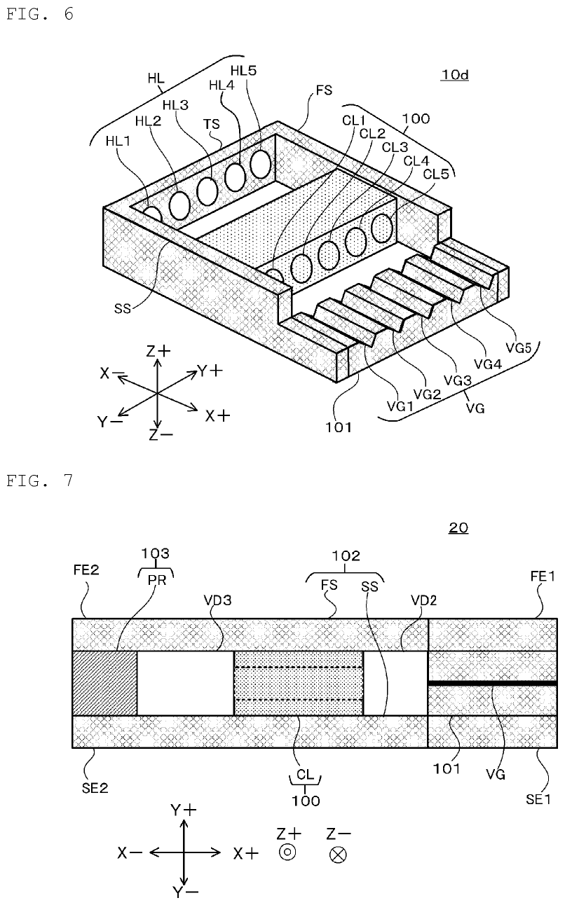

Hereinafter, an optical coupler 10c according to a modification of the optical coupler 10b will be described with reference to the drawings. FIG. 5 is a top view of the optical coupler 10c according to the modification of the optical coupler 10b. In FIG. 5, the optical fiber OF is not illustrated. The optical coupler 10c is different from the optical coupler 10b in that the second optical member 103 and the first collimator lens 1040 are integrally molded. For example, the second optical member 103 and the first collimator lens 1040 are integrally molded by using the same material as a main component. The main component of the second optical member 103 and the main component of the first collimator lens 1040 are, for example, quartz glass, borosilicate glass, or the like. In other words, the second optical member 103 and at least one collimator lens are integrally molded by using materials having an identical main component. Note that, in the optical coupler 10c, the same configurations as those of the optical coupler 10b are denoted by the same reference symbols, and description thereof is omitted.

### (Effect of Optical Coupler 10c)

According to the optical coupler 10c, the strength of the optical coupler 10c is increased. More specifically, the second optical member 103 and at least one collimator lens (first collimator lens 1040) are integrally molded. The second optical member 103 and the first collimator lens 1040 are integrally molded, and thus, the rigidity of the second optical member 103 and the first collimator lens 1040 is enhanced. Accordingly, the strength of the optical coupler 10c is increased.

In addition, the optical coupler 10c is hardly damaged. For example, when the second optical member and the first collimator lens are integrally molded by materials having different main components, the second optical member and the first collimator lens have different coefficients of thermal expansion. In this case, there is a possibility that a deformation amount of the second optical member and a deformation amount of the first collimator lens are different depending on a difference in coefficient of thermal expansion. As a result, there is a possibility that the integrally molded second optical member and first collimator lens are damaged. On the other hand, in the optical coupler 10c, the second optical member 103 and at least one collimator lens (first collimator lens 1040) are integrally molded by using materials having an identical main component. Accordingly, the coefficient of thermal expansion of the second optical member 103 and the coefficient of thermal expansion of the first collimator lens 1040 are easily identical. Accordingly, there is a low possibility that the integrally molded second optical member 103 and first collimator lens 1040 are damaged. As a result, the optical coupler 10c is hardly damaged.

According to the optical coupler 10c, the optical coupler 10c can be downsized. More specifically, the second optical member 103 and at least one collimator lens (first collimator lens 1040) are integrally molded. In this case, the second optical member 103 and the first collimator lens 1040 are disposed with no interval therebetween. Accordingly, a length of the optical coupler 10c in the X-axis direction is shorter than that in a case where the second optical member 103 and the first collimator lens 1040 are disposed at intervals. As a result, the optical coupler 10c can be downsized.

### (Third Modification of Optical Coupler 10)

Hereinafter, an optical coupler 10d according to a third modification of the optical coupler 10 will be described with reference to the drawings. FIG. 6 is an external perspective view of the optical coupler 10d according to the third modification of the optical coupler 10. In FIG. 6, optical fibers OF1 to OF5 are not illustrated. The optical coupler 10d is different from the optical coupler 10 in that the first optical member 100 includes two or more condensing lenses CL and the fixing unit 101 includes two or more grooves VG. Details will be described below. Note that, in the optical coupler 10d, the same configurations as those of the optical coupler 10 are denoted by the same reference symbols, and description thereof is omitted.

As illustrated in FIG. 6, in the present modification, the first optical member 100 includes condensing lenses CL1 to CL5. The condensing lenses CL1 to CL5 are arranged at intervals in this order in the positive direction of the Y-axis. In other words, two or more condensing lenses CL are arranged in the Y-axis direction and do not overlap each other as viewed in the Z-axis direction.

The fixing unit 101 includes grooves VG1 to VG5. The grooves VG1 to VG5 are arranged at intervals in this order in the positive direction of the Y-axis. The grooves VG1 to VG5 do not overlap each other as viewed in the Z-axis direction. In other words, two or more grooves VG are arranged in the Y-axis direction and do not overlap each other as viewed in the Z-axis direction. The optical fibers OF1 to OF5 (not illustrated) are fixed to the grooves VG1 to VG5, respectively. The optical fibers OF1 to OF5 are optically coupled to the condensing lenses CL1 to CL5, respectively. Specifically, lasers La1 to La5 (not illustrated) having passed through through-holes HL1 to HL5 are incident on the condensing lenses CL1 to CL5, respectively. The optical fibers OF1 to OF5 receive the lasers La1 to La5, respectively. The optical coupler 10d can achieve the same actions and effects as those of the optical coupler 10.

### Second Embodiment

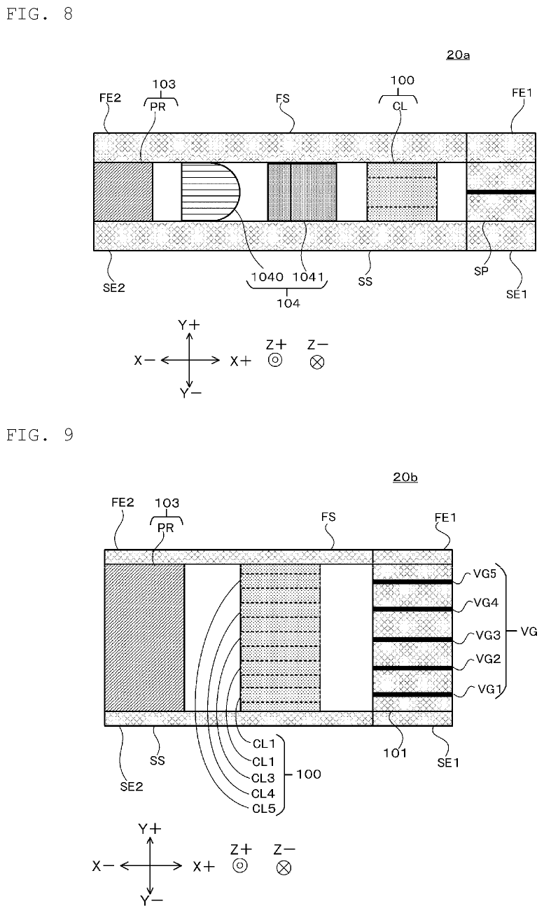

Hereinafter, an optical coupler 20 according to a second embodiment will be described with reference to the drawings. FIG. 7 is a top view of the optical coupler 20 according to the second embodiment. In FIG. 7, the optical fiber OF is not illustrated. As illustrated in FIG. 7, the optical coupler 20 is different from the optical coupler 10 in that the support member 102 does not include the third portion TS. Specifically, in the optical coupler 20, the second optical member 103 is fixed to the first-portion second end portion FE2 and the second-portion second end portion SE2 instead of the third portion TS. Details will be described below. Note that, the same structures as those of the optical coupler 10 are denoted by the same reference symbols, and description thereof is omitted.

As illustrated in FIG. 7, the optical coupler 20 includes the first optical member 100, the second optical member 103, the fixing unit 101, and the support member 102. The second optical member 103, the first optical member 100, the fixing unit 101, and the support member 102 are disposed not to overlap each other as viewed in the Z-axis direction. Specifically, the second optical member 103, the first optical member 100, and the fixing unit 101 are arranged at intervals in this order in the positive direction of the X-axis.

The second optical member 103 includes one or more prisms PR. Since the structure of the prism PR is the same as that of the prism PR of the optical coupler 10a, the description thereof is omitted.

In the present embodiment, the support member 102 has the first portion FS and the second portion SS. As illustrated in FIG. 7, the first portion FS is present at a position different from the second portion SS in the Y-axis direction. Specifically, the first portion FS and the second portion SS are arranged at intervals in this order in the negative direction of the Y-axis. In addition, the second optical member 103, the first optical member 100, and the fixing unit 101 are positioned between the first portion FS and the second portion SS in the Y-axis direction. In this case, a gap VD3 is present between the second optical member 103 and the first optical member 100. The gap VD3 penetrates the optical coupler 10 in the Z-axis direction (see FIG. 7).

The first portion FS extends in the X-axis direction. The first optical member 100 is fixed to the first portion FS. In addition, the fixing unit 101 is fixed to the first portion FS. In the present embodiment, the fixing unit 101 is fixed to the first-portion first end portion FE1. Further, the second optical member 103 is fixed to the first portion FS. In the present embodiment, the second optical member 103 is fixed to the first-portion second end portion FE2.

The second portion SS extends in the X-axis direction. The first optical member 100 is fixed to the second portion SS. In addition, the fixing unit 101 is fixed to the second portion SS. In the present embodiment, the fixing unit 101 is fixed to the second-portion first end portion SE1. Further, the second optical member 103 is fixed to the second portion SS. In the present embodiment, the second optical member 103 is fixed to the second-portion second end portion SE2.

### Effects of Second Embodiment

According to the optical coupler 20, it is possible to reduce a possibility that an optical axis of the optical coupler 20 is shifted. More specifically, the second optical member 103, the first optical member 100, and the fixing unit 101 are arranged at intervals in this order in the positive direction of the X-axis, and the first optical member 100 is fixed to the first portion FS and the second portion SS between the second optical member 103 and the fixing unit 101. In the case of the above configuration, the first optical member 100 is fixed to the first portion FS and the second portion SS between the second optical member 103 and the fixing unit 101. Accordingly, similarly to the optical coupler 10, the first portion FS is hardly deformed at and in the vicinity of the center of the first portion FS in the X-axis direction. In addition, the second portion SS is hardly deformed at and in the vicinity of the center of the second portion SS in the X-axis direction. Accordingly, the possibility that the optical axis of the optical coupler 20 is shifted is reduced.

### First Modification of Second Embodiment

Hereinafter, an optical coupler 20a according to a first modification of the second embodiment will be described with reference to the drawings. FIG. 8 is a top view of the optical coupler 20a according to the second embodiment. In FIG. 8, the optical fiber OF is not illustrated. The optical coupler 20a is different from the optical coupler 20 in that the third optical member 104 is provided. Details will be described below. Note that, in the optical coupler 20a, the same configurations as those of the optical coupler 20 are denoted by the same reference symbols, and description thereof is omitted.

As illustrated in FIG. 8, the third optical member 104 is sandwiched between the first optical member 100 and the second optical member 103 in the X-axis direction. The third optical member 104 includes one or more collimator lenses. Specifically, in the present modification, the third optical member 104 includes the first collimator lens 1040 and the second collimator lens 1041. The structure and disposition of the first collimator lens 1040 and the second collimator lens 1041 are similar to those of the optical coupler 10b, and thus, the description thereof will be omitted.

Similarly to the optical coupler 10b, in the optical coupler 20a, the first collimator lens 1040 and the second collimator lens 1041 positioned between the second optical member 103 and the fixing unit 101 reduce the possibility that an optical axis of the optical coupler 20a is shifted.

### Second Modification of Second Embodiment

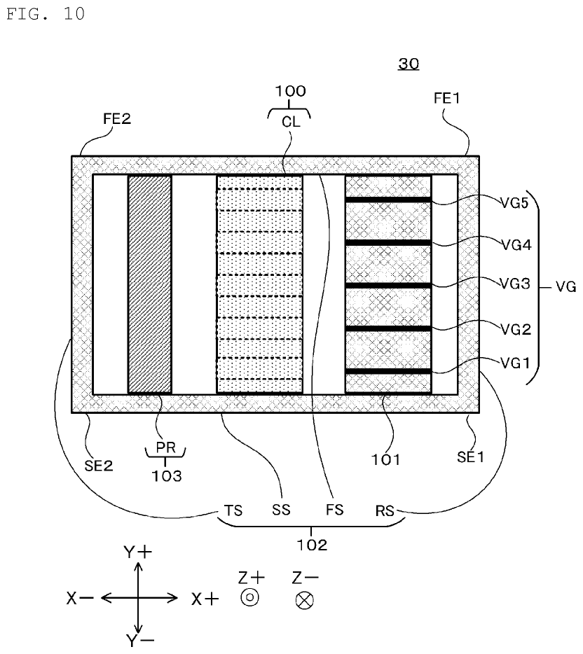

Hereinafter, an optical coupler 20b according to a second modification of the second embodiment will be described with reference to the drawings. FIG. 9 is a top view of the optical coupler 20b according to the second modification of the optical coupler 20. In FIG. 9, the optical fibers OF1 to OF5 are not illustrated.

The optical coupler 20b is different from the optical coupler 20 in that the first optical member 100 includes two or more condensing lenses CL and the fixing unit 101 includes two or more grooves VG. Details will be described below. Note that, in the optical coupler 20b, the same configurations as those of the optical coupler 20 are denoted by the same reference symbols, and description thereof is omitted.

As illustrated in FIG. 9, in the optical coupler 20b, the first optical member 100 includes the condensing lenses CL1 to CL5. The fixing unit 101 of the optical coupler 20b includes the grooves VG1 to VG5. The optical fibers OF1 to OF5 (not illustrated) are fixed to the grooves VG1 to VG5, respectively. The lasers La1 to La5 (not illustrated) emitted to the second optical member 103 are incident on the condensing lenses CL1 to CL5. Since the structure and disposition of the condensing lenses CL1 to CL5 and the structure and disposition of the grooves VG1 to VG5 are the same as those of the optical coupler 10d, the description thereof will be omitted.

### Third Embodiment

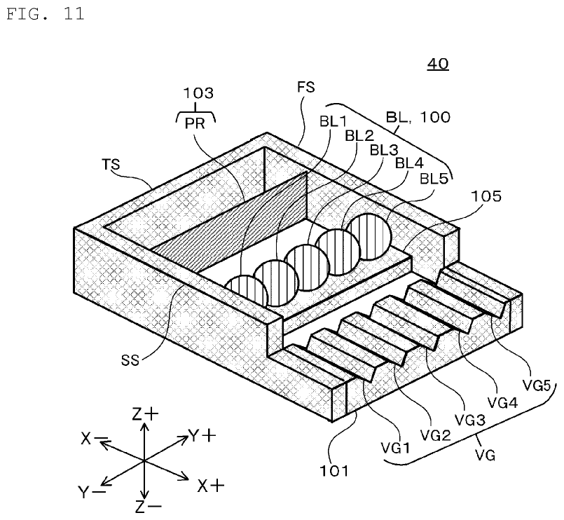

Hereinafter, an optical coupler 30 according to a third embodiment will be described with reference to the drawings. FIG. 10 is a top view of the optical coupler 30 according to a third embodiment. In FIG. 10, the optical fiber OF is not illustrated. The optical coupler 30 is different from the optical coupler 10 in that the support member 102 includes a fourth portion RS. Details will be described below. Note that, in the optical coupler 30, the same configurations as those of the optical coupler 10 are denoted by the same reference symbols, and description thereof is omitted.

As illustrated in FIG. 10, the fourth portion RS is fixed to the first-portion first end portion FE1 and the second-portion first end portion SE1. At this time, the third portion TS, the second optical member 103, the first optical member 100, the fixing unit 101, and the fourth portion RS are arranged in this order at intervals in the positive direction of the X-axis. In this case, the first portion FS and the second portion SS are hardly deformed by the fixing unit 101 positioned between the fourth portion RS and the first optical member 100. Accordingly, for the same reason as the optical coupler 10, a possibility that an optical axis of the optical coupler 30 is shifted is reduced.

### Fourth Embodiment

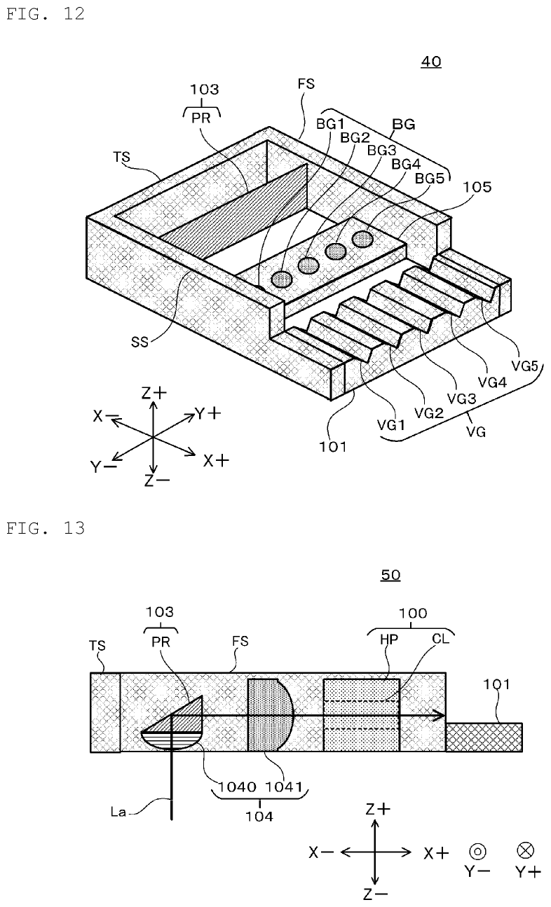

Hereinafter, an optical coupler 40 according to a fourth embodiment will be described with reference to the drawings. FIG. 11 is an external perspective view of the optical coupler 40 according to the fourth embodiment. In FIG. 11, the optical fiber OF is not illustrated. FIG. 12 is an external perspective view of the optical coupler 40, and is a diagram in which ball lenses BL1 to BL5 are not illustrated. The optical coupler 40 is different from the optical coupler 10 in including one or more ball lenses BL and a ball lens fixing unit 105. Details will be described below. Note that, in the optical coupler 40, the same configurations as those of the optical coupler 10 are denoted by the same reference symbols, and description thereof is omitted.

In the example illustrated in FIG. 11, the first optical member 100 of the optical coupler 40 includes the ball lenses BL1 to BL5. The ball lenses BL1 to BL5 are spherical condensing lenses. The ball lenses BL1 to BL5 are arranged in this order in the positive direction of the Y-axis.

As illustrated in FIGS. 11 and 12, the ball lens fixing unit 105 is fixed to the end portion of the first portion FS in the negative direction of the Z-axis. In addition, the ball lens fixing unit 105 is fixed to the end portion of the second portion SS in the negative direction of the Z axis. The third portion TS, the second optical member 103, the ball lens fixing unit 105, and the fixing unit 101 are arranged in this order at intervals in the positive direction of the X-axis. The ball lens fixing unit 105, the support member 102, and the fixing unit 101 are integrally molded by using materials having an identical main component.

The ball lens fixing unit 105 fixes one or more ball lenses BL. Specifically, as illustrated in FIG. 12, the ball lens fixing unit 105 includes one or more recesses BG. One or more ball lenses BL are fixed to one or more recesses BG. In the example illustrated in FIG. 12, the ball lens fixing unit 105 includes recesses BG1 to BG5. The recesses BG1 to BG5 are arranged in this order in the positive direction of the Y-axis. In the example illustrated in FIG. 11, the ball lenses BL1 to BL5 are fixed to the recesses BG1 to BG5, respectively.

In the present modification, the first portion FS and the second portion SS are hardly deformed by the ball lens fixing unit 105. Accordingly, for the same reason as the optical coupler 10, a possibility that an optical axis of the optical coupler 40 is shifted is reduced.

### Fifth Embodiment

Hereinafter, an optical coupler 50 according to a fifth embodiment will be described with reference to the drawings. FIG. 13 is a sectional view of the optical coupler 50 according to the fifth embodiment. FIG. 13 corresponds to a sectional view taken along the line A-A in FIG. 3. In FIG. 13, the optical fiber OF is not illustrated. The optical coupler 50 is different from the optical coupler 10 in including the second optical member 103 and the third optical member 104 arranged in the Z-axis direction. Details will be described below. Note that, in the optical coupler 50, the same configurations as those of the optical coupler 10 are denoted by the same reference symbols, and description thereof is omitted.

In the optical coupler 50, the second optical member 103 and at least one collimator lens are arranged in the positive direction of the Z axis. For example, as illustrated in FIG. 13, the first collimator lens 1040 and the second optical member 103 are arranged in this order in the positive direction of the Z-axis. In this case, the laser La traveling in the positive direction of the Z axis is incident on the first collimator lens 1040. For example, the light of the laser La spreading in the fast axis direction is corrected by the first collimator lens 1040. The corrected laser La reaches the second optical member 103. The traveling direction of the laser La changes from the positive direction of the Z axis to the positive direction of the X-axis by the second optical member 103. The laser La traveling in the positive direction of the X-axis passes through the second collimator lens 1041 and the first optical member 100 and reaches the optical fiber OF. For the same reason as the optical coupler 10, the optical coupler 50 reduces a possibility that an optical axis of the optical coupler 50 is shifted.

### Other Embodiments

The present invention is not limited to the optical couplers 10, 10a, 10b, 10c, 10d, 20, 20a, 20b, 30, 40, and 50 according to the present invention, and can be modified within the scope of the gist thereof. In addition, the structures of the optical couplers 10, 10a, 10b, 10c, 10d, 20, 20a, 20b, 30, 40, and 50 may be voluntarily combined.

Note that, the optical couplers 10, 10a, 10b, 10c, 10d, 20, 20a, 20b, 30, 40, and 50 are used, for example, in the field of optical communication. For example, the optical couplers 10, 10a, 10b, 10c, 10d, 20, 20a, 20b, 30, 40, and 50 are used in optical transceivers.

Note that, the first optical member 100 may not necessarily include one or more condensing lenses.

Note that, the second optical member 103 may not necessarily include the prism PR.

Note that, in the optical couplers 10 and 10c, the laser La may not necessarily reach the first optical member 100 through the through-hole HL. For example, in the optical couplers 10 and 10c, the laser La may reach the first optical member 100 by shortening the length of the third portion TS in the Z-axis direction.

Note that, in the optical couplers 10b and 20a, the second optical member 103 and the first collimator lens 1040 may be a single member made of a single material.

Note that, the optical coupler 10 may include the first collimator lens 1040 and the second collimator lens 1041.

Note that, in the optical couplers 10c and 20b, the first optical member 100 may not necessarily include the five condensing lenses. Similarly, in the optical couplers 10c and 20b, the fixing unit 101 may not necessarily include five grooves VG.

Note that, in the optical coupler 30, the first optical member 100 may not necessarily include two or more condensing lenses CL. The first optical member 100 may include only one condensing lens. In this case, the fixing unit 101 includes one groove VG. One optical fiber OF is fixed to the fixing unit 101.

Note that, in the optical coupler 40, the first optical member 100 may not necessarily include five ball lenses BL. The optical coupler 40 may include six or more ball lenses BL. In addition, the optical coupler 40 may include 1 to 4 ball lenses BL.

Note that, the optical coupler 40 may not necessarily include the prism PR. For example, the through-hole HL is provided in the third portion TS of the optical coupler 40. The laser La may reach the first optical member 100 through the through-hole HL.

Note that, in the optical couplers 10, 10a, 10b, 10c, 30, 40, and 50, the third portion TS may not be necessarily fixed to the first-portion second end portion FE2. For example, the third portion TS may be fixed to the first portion FS between the first-portion first end portion FE1 and the first-portion second end portion FE2. Similarly, the third portion TS may not be necessarily fixed to the second-portion second end portion SE2.

Similarly, the fixing unit 101 may not be necessarily fixed to the first-portion first end portion FE1. Similarly, the fixing unit 101 may not be fixed to the second-portion first end portion SE1.

Similarly, in the optical coupler 30, the fourth portion RS may not be necessarily fixed to the first-portion first end portion FE1. Similarly, the fourth portion RS may not be fixed to the second-portion first end portion SE1.

Note that, the optical coupler 40 may include one or more third optical members 104.

Note that, the support member 102 may not necessarily include a glass material having a filler.

Note that, the groove VG may not necessarily have a V shape as viewed in the X-axis direction.

Note that, in the optical couplers 10 and 10d, the third portion TS, the first optical member 100, and the fixing unit 101 may be arranged at equal intervals in the X-axis direction. In this case, for example, the force A applied to the first portion FS is easily dispersed throughout the first portion FS. Accordingly, the optical couplers 10 and 10d are hardly deformed. As a result, the possibility that the optical axes of the optical couplers 10 and 10d are shifted is reduced.

Similarly, in the optical couplers 10a and 40, the third portion TS, the second optical member 103, the first optical member 100, and the fixing unit 101 may be arranged at equal intervals in the X-axis direction.

Similarly, in the optical coupler 10b, the third portion TS, the second optical member 103, the third optical member 104, the first optical member 100, and the fixing unit 101 may be arranged at equal intervals in the X-axis direction.

Similarly, in the optical coupler 10c, the third portion TS, the integrally molded second optical member 103 and first collimator lens 1040, the second collimator lens 1041, the first optical member 100, and the fixing unit 101 may be arranged at equal intervals.

Similarly, in the optical couplers 20 and 20b, the second optical member 103, the first optical member 100, and the fixing unit 101 may be arranged at equal intervals in the X-axis direction.

Similarly, in the optical coupler 20a, the second optical member 103, the third optical member 104, the first optical member 100, and the fixing unit 101 may be arranged at equal intervals in the X-axis direction.

Similarly, in the optical coupler 30, the third portion TS, the second optical member 103, the first optical member 100, the fixing unit 101, and the fourth portion RS may be arranged at equal intervals in the X-axis direction.

Note that, the support member 102 and the fixing unit 101 may contain a glass material having a filler. In this case, the support member 102 and the fixing unit 101 are made of materials having an identical main component. Accordingly, the rigidity of the optical couplers 10, 10a, 10b, 10c, 10d, 20, 20a, 20b, 30, 40, and 50 is increased.

Note that, all the members (first optical member 100, fixing unit 101, support member 102, and the like) included in the optical couplers 10, 10a, 10b, 10c, 10d, 20, 20a, 20b, 30, 40, and 50 may be integrally molded by using materials having an identical main component.

Note that, in the examples illustrated in FIGS. 1 to 11, the length of the first portion FS in the Z-axis direction at the first-portion first end portion FE1 is different from the length of the first portion FS in the Z-axis direction at the first-portion second end portion FE2. However, the length of the first portion FS in the Z-axis direction at the first-portion first end portion FE1 and the length of the first portion FS in the Z-axis direction at the first-portion second end portion FE2 may be the same.

Note that, in the examples illustrated in FIGS. 1 to 11, the length of the second portion SS in the Z-axis direction at the second-portion first end portion SE1 is different from the length of the second portion SS in the Z-axis direction at the second-portion second end portion SE2. However, the length of the second portion SS in the Z-axis direction at the second-portion first end portion SE1 and the length of the second portion SS in the Z-axis direction at the second-portion second end portion SE2 may be the same.

Note that, in the first embodiment and the second embodiment, the case where the laser La is incident on the optical fiber OF has been described as an example. However, the optical couplers 10, 10a, 10b, 10c, 10d, 20, 20a, 20b, 30, and 40 can also be used, for example, in a case where the laser La is output from the optical fiber OF. Hereinafter, description will be made with reference to FIG. 3.

For example, in FIG. 3, the laser La is emitted from the optical fiber OF. That is, the laser La is irradiated in the negative direction of the X-axis. The laser La passes through the first optical member 100 and reaches the prism PR. At this time, the prism PR changes the traveling direction of the laser La from the X-axis direction to the Z-axis direction. The laser La of which the traveling direction has been changed to the Z-axis direction is emitted to the outside of the optical couplers 10, 10a, 10b, 10c, 10d, 20, 20a, 20b, 30, and 40. That is, the second optical member 103 may include the prism PR that changes the traveling direction of the light from the X-axis direction to the Z-axis direction.

Note that, in the description of the optical couplers 10d and 20b, the case where the lasers La1 to La5 are incident on the optical fibers OF1 to OF5 has been described as an example. However, a part of the optical fibers OF1 to OF5 may be an optical fiber that outputs the laser La. For example, in the optical coupler 10d, the optical fibers OF1 to OF3 may be optical fibers on which light is incident, and the optical fibers OF4 and OF5 may be optical fibers from which laser is emitted.

Note that, in the optical couplers 10b, 10c, and 20a, the first collimator lens 1040 and the second collimator lens 1041 may not be necessarily arranged in this order in the positive direction of the X-axis. For example, the second collimator lens 1041 and the first collimator lens 1040 may be arranged in this order in the positive direction of the X-axis.

Note that, in the optical coupler 50, the second collimator lens 1041, and the second optical member 103 may be arranged in the positive direction of the Z axis.

Note that, in the optical coupler 40, the ball lens fixing unit 105, the support member 102, and the fixing unit 101 may not be necessarily integrally molded by using materials having an identical main component.

### DESCRIPTION OF REFERENCE SYMBOLS

10, 10a, 10b, 10c, 10d, 20, 20a, 20b, 30, 40, 50: Optical coupler
100: First optical member
CL, CL1 to CL5: Condensing lens
101: Fixing unit
OF, OF1 to OF5: Optical fiber
102: Support member
FS: First portion
SS: Second portion
TS: Third portion
103: Second optical member
PR: Prism
104: Third optical member
1040: First collimator lens
1041: Second collimator lens

1. An optical coupler comprising:
a first optical member including one or more condensing lenses that concentrate light traveling in a positive direction of an X-axis;
a fixing unit that fixes one or more optical fibers; and
a support member having a first portion extending in the X-axis direction, a second portion extending in the X-axis direction, and a third portion extending in a Y-axis direction orthogonal to the X-axis direction,
wherein
the first portion is present at a position different from the second portion in the Y-axis direction,
the first optical member, the fixing unit, and the support member are disposed not to overlap each other as viewed in a Z-axis direction orthogonal to the X-axis direction and the Y-axis direction,
the third portion, the first optical member, and the fixing unit are arranged at intervals in this order in the positive direction of the X-axis,
the third portion, the first optical member, and the fixing unit are positioned between the first portion and the second portion as viewed in the Z-axis direction, and
each of the third portion, the first optical member, and the fixing unit are fixed to the first portion and the second portion.

2. The optical coupler according to claim 1, wherein
an end portion of the first portion in the positive direction of the X-axis is a first-portion first end portion,
an end portion of the first portion in a negative direction of the X-axis is a first-portion second end portion,
an end portion of the second portion in the positive direction of the X-axis is a second-portion first end portion,
an end portion of the second portion in the negative direction of the X-axis is a second-portion second end portion,
the third portion is fixed to the first-portion second end portion and the second-portion second end portion, and
the fixing unit is fixed to the first-portion first end portion and the second-portion first end portion.

3. The optical coupler according to claim 1, further comprising a second optical member between the third portion and the first optical member in the X-axis direction, the second optical member being fixed to the first portion and the second portion as viewed in the Z-axis direction,
wherein
the second optical member does not overlap the fixing unit and the support member as viewed in a Z-axis direction, and
the second optical member includes a prism that changes a traveling direction of light from a Z-axis direction to an X-axis direction orthogonal to the Z-axis direction or a prism that changes the traveling direction of the light from the X-axis direction to the Z-axis direction.

4. The optical coupler according to claim 3, further comprising a third optical member positioned between the first optical member and the second optical member in the X-axis direction, the third optical member being fixed to the first portion and the second portion,
wherein
the third optical member is disposed not to overlap the second optical member, the first optical member, the fixing unit, and the support member as viewed in a Z-axis direction, and
the third optical member includes one or more collimator lenses.

5. The optical coupler according to claim 4, wherein the second optical member and at least one collimator lens of the one or more collimator lenses are an integrally molded body, the second optical member and the at least one collimator lens being made of materials having an identical main component.

6. The optical coupler according to claim 1, wherein the optical fiber and the condensing lens arranged in the X-axis direction are optically coupled.

7. The optical coupler according to claim 1, wherein the fixing unit includes one or more grooves having a V shape as viewed in the X-axis direction.

8. The optical coupler according to claim 7, wherein
the fixing unit includes two or more grooves arranged in the Y-axis direction, and do not overlap each other as viewed in the Z-axis direction,
two or more condensing lenses are arranged in the Y-axis direction, and do not overlap each other as viewed in the Z-axis direction, and
the optical fiber and the condensing lens arranged in the X-axis direction are optically coupled.

9. The optical coupler according to claim 1, wherein the support member contains a glass material having a filler.

10. The optical coupler according to claim 9, wherein the fixing unit contains a glass material having a filler.

11. An optical coupler comprising:
a first optical member including one or more condensing lenses that concentrate light;
a second optical member including a prism that changes a traveling direction of light from a Z-axis direction to an X-axis direction orthogonal to the Z-axis direction or a prism that changes the traveling direction of the light from the X-axis direction to the Z-axis direction;
a fixing unit that fixes one or more optical fibers; and
a support member having a first portion extending in the X-axis direction and a second portion extending in the X-axis direction,
wherein
the first portion is present at a position different from the second portion in a Y-axis direction orthogonal to the Z-axis direction and the X-axis direction,
the second optical member, the first optical member, the fixing unit, and the support member are disposed not to overlap each other as viewed in a Z-axis direction,
the second optical member, the first optical member, and the fixing unit are arranged at intervals in this order in a positive direction of the X-axis,
the second optical member, the first optical member, and the fixing unit are positioned between the first portion and the second portion in the Y-axis direction, and
each of the second optical member, the first optical member, and the fixing unit is fixed to the first portion and the second portion.

12. The optical coupler according to claim 11, wherein
an end portion of the first portion in the positive direction of the X-axis is a first-portion first end portion,
an end portion of the first portion in a negative direction of the X-axis is a first-portion second end portion,
an end portion of the second portion in the positive direction of the X-axis is a second-portion first end portion,
an end portion of the second portion in the negative direction of the X-axis is a second-portion second end portion,
the second optical member is fixed to the first-portion second end portion and the second-portion second end portion, and
the fixing unit is fixed to the first-portion first end portion and the second-portion first end portion.

13. The optical coupler according to claim 11, further comprising a third optical member positioned between the first optical member and the second optical member in the X-axis direction, the third optical member being fixed to the first portion and the second portion,
wherein
the third optical member is disposed not to overlap the second optical member, the first optical member, the fixing unit, and the support member as viewed in a Z-axis direction, and
the third optical member includes one or more collimator lenses.

14. The optical coupler according to claim 13, wherein the second optical member and at least one collimator lens of the one or more collimator lenses are an integrally molded body, the second optical member and the at least one collimator lens being made of materials having an identical main component.

15. The optical coupler according to claim 11, wherein the optical fiber and the condensing lens arranged in the X-axis direction are optically coupled.

16. The optical coupler according to claim 11, wherein the fixing unit includes one or more grooves having a V shape as viewed in the X-axis direction.

17. The optical coupler according to claim 16, wherein
the fixing unit includes two or more grooves arranged in the Y-axis direction, and do not overlap each other as viewed in the Z-axis direction,
two or more condensing lenses are arranged in the Y-axis direction, and do not overlap each other as viewed in the Z-axis direction, and
the optical fiber and the condensing lens arranged in the X-axis direction are optically coupled.

18. The optical coupler according to claim 11, wherein the support member contains a glass material having a filler.

19. The optical coupler according to claim 18, wherein the fixing unit contains a glass material having a filler.
